(19) United States
(12) Patent Application Publication
(10) Pub. No.: US 2012/0255932 A1
(43) Pub. Date: Oct. 11, 2012

(54) NANOFABRICATION DEVICE AND METHOD FOR MANUFACTURE OF A NANOFABRICATION DEVICE

(76) Inventors: Massood Tabib-Azar, Salt Lake City, UT (US); Carlos H. Mastrangelo, Salt Lake City, UT (US)

(21) Appl. No.: 13/249,093

(22) Filed: Sep. 29, 2011

Related U.S. Application Data
(63) Continuation-in-part of application No. 13/184,260, filed on Jul. 15, 2011, now abandoned.
(60) Provisional application No. 61/399,655, filed on Jul. 15, 2010.
(60) Provisional application No. 61/446,351, filed on Feb. 24, 2011.

(51) Int. Cl. C23C 16/50; C23C 16/56; H05H 1/24; C23C 16/455; B44C 1/22

(52) U.S. Cl. 216/63; 118/723 R; 118/712; 156/345.33; 156/345.24; 427/457; 427/569; 427/271; 427/123

(57) ABSTRACT

A nanofabrication device in an example includes a conducting nanotip and a gas microchannel adjacent to the nanotip and configured to deliver a gas to the nanotip. The nanofabrication device can be used for controlled and localized etching and/or deposition of material from a substrate.

### RELATED APPLICATIONS

This application is a continuation-in-part of U.S. patent application Ser. No. 13/184,260, filed Jul. 15, 2011 which claims the benefit of U.S. Provisional Patent Application No. 61/399,655, filed Jul. 15, 2010 which are each incorporated herein by reference.

This application also claims the benefit of U.S. Provisional Patent Application No. 61/446,351, filed Feb. 24, 2011, which is also incorporated herein by reference.

### GOVERNMENT INTEREST

This invention was made with government support under Award #N66001-08-1-2042 awarded by the U.S. Department of Defense/Defense Advanced Research Projects Agency. The Government has certain rights in the invention.

### BACKGROUND

Various lithographic patterning and manufacturing processes exist for structuring material on a fine scale. Such processes are often referred to as microlithography or nanolithography. Some example lithography processes include electron beam lithography, nanoimprint lithography, interference lithography, X-ray lithography, extreme ultraviolet lithography, magnetolithography, surface charge lithography, and scanning probe lithography.

Another common example of nanolithography is photolithography. Photolithography is often applied to semiconductor manufacturing of microchips and fabrication of micro-electrical-mechanical system (MEMS) devices. In photolithographic processes parts of a thin film or the bulk of a substrate can be selectively removed. More specifically, photolithography uses light to transfer a pattern from a photo mask to a light-sensitive chemical “photoresist” (or “resist”) on the substrate. Chemical treatments can be used to engrave a pattern into material underneath the resist or to deposit a new material in the pattern upon the material underneath the resist.

Nanomanufacture involving photolithography typically involves several steps performed in a sequence. For example, a surface may be cleaned and prepared using application of various chemicals, heat, promoters, and so forth. A layer of a material can be applied to the surface. The layer can be covered with the resist, such as by spin coating. The resist-coated surface is then prebaked to remove excess photoresist solvent. The resist is then exposed to a pattern of light. Exposed portions of the resist can undergo a chemical change that allows some of the resist to be removed by a special solution. The resulting structure is then “hard-baked” to solidify the remaining resist. Next a chemical agent can be used to remove or etch material from a layer exposed by the removed portions of the resist. After etching, the resist is no longer needed and is removed from the substrate by applying a resist stripper or through oxidization.

Photolithography and other lithographic techniques thus involve many steps of adding, removing, and treating materials to form desired patterns and structures.

### SUMMARY

A nanofabrication device can include a conducting nanotip and a gas microchannel adjacent to the nanotip which is configured to deliver a gas to the nanotip.

A method of nanofabrication can include positioning a conducting nanotip in a desired location proximal to a substrate. A precursor gas can be delivered to the nanotip through a gas microchannel adjacent to the nanotip. The precursor gas can be decomposed to form a solid product by exposing the precursor gas to an electric field using the nanotip such that the solid product deposits on the substrate.

A method of manufacturing a nanofabrication device can include depositing a base material for use as nanotip on a substrate. A sacrificial layer can be deposited over the base material and a microchannel layer can be deposited over the sacrificial layer. The sacrificial layer can be dissolved, leaving a microchannel between the microchannel layer and the base material. The base material can be oxidized to sharpen the base material to form the nanotip.

Additional variations and aspects of the invention can be appreciated from the following detailed description.

### BRIEF DESCRIPTION OF THE DRAWINGS

FIGS. 1a-1c are respectively perspective, bottom and SEM (Scanning Electron Microscope) views of a probe and tip region of the probe in accordance with an example of the present technology.

FIG. 2 is an atomic force microscope image of silicon dots deposited on silicon by functionalized AFM tip using SiCl₄ on silicon in accordance with an example of the present technology.

FIG. 3 is a Paschen curve calculated for Argon at different pressures as a function of electrode gap in the device in accordance with an example of the present technology.

FIG. 4 is a side view of gas ionization near the functionalized tip and deposition of heavy ions under the apex in accordance with an example of the present technology.

FIG. 5 is a schematic diagram of “coupling” of a probe and an insulating substrate to direct Ar⁺ ions toward the sample to etch and correct deposits in accordance with an example of the present technology.

FIG. 6a is a top partial cutaway view of a functionalized probe with dual piezoelectric actuators and piezoresistive deflection sensors in accordance with an example of the present technology.

FIGS. 6b-6d are side views of a functionalized probe illustrating movement of a support beam with respect to a substrate when actuators are moved in and out of sync with respect to one another in accordance with examples of the present technology.

FIG. 7 is a schematic diagram of a sigma-delta tracking loop to sense and control a functionalized probe's tip in accordance with an example of the present technology.

FIG. 8 is a micrograph of helium microplasma operating at atmospheric pressure in an array in accordance with an example of the present technology.

FIG. 9 is a flow diagram of a method of nanofabrication in accordance with an example of the present technology.

FIG. 10 is a schematic diagram of a deposition chamber for use with a probe in accordance with an example of the present technology.

FIG. 11 is a block diagram side cutaway view of a fabrication system including different micro-chambers enclosing groups of parallel local probes to deposit different materials in parallel in accordance with an example of the present technology.

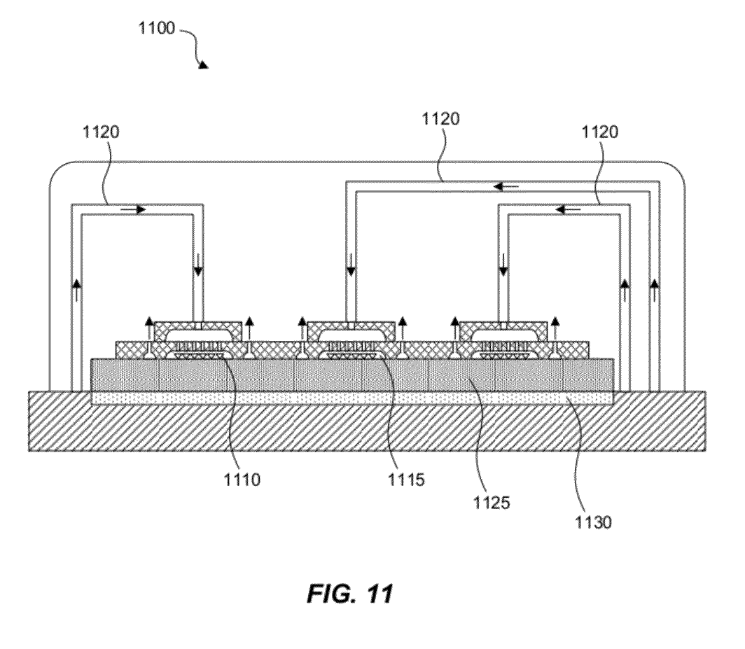

FIGS. 12a-12b are respectively simplified cross-section and top views of the nanotips in accordance with an example of the present technology.

FIGS. 13a-13e illustrate a simplified process flow of manufacturing a nanotorch device in accordance with an example of the present technology.

FIGS. 14a-14d are SEM images at various magnifications of a microfabricated nanotorch on a suspended cantilever beam approximately 500 μm long in accordance with an example of the present technology.

FIG. 15 is a flow diagram of a method of manufacturing a nanofabrication device in accordance with an example of the present technology.

FIG. 16 is a perspective cross-sectional view of a probe with piezoelectric/thermal actuators and piezoresistor sensors in accordance with an example of the present technology.

FIG. 17 is an electronics block diagram illustrating a system for sensing and actuating a probe in accordance with an example of the present technology.

### DETAILED DESCRIPTION

Before the present disclosure is described herein, it is to be understood that this disclosure is not limited to the particular structures, process steps, or materials disclosed herein, but is extended to equivalents thereof as would be recognized by those ordinarily skilled in the relevant arts. It should also be understood that terminology employed herein is used for the purpose of describing particular embodiments only and is not intended to be limiting.

The following terminology will be used in accordance with the definitions set forth below.

As used herein, “electrically coupled” refers to a relationship between structures that allows electrical current to flow at least partially between them. This definition is intended to include aspects where the structures are in physical contact and those aspects where the structures are not in physical contact. Typically, two materials which are electrically coupled can have an electrical potential or actual current between the two materials. For example, two plates physically connected together by a resistor are in physical contact, and thus allow electrical current to flow between them. Conversely, two plates separated by a dielectric material are not in physical contact, but, when connected to an alternating current source, allow electrical current to flow between them by capacitive means. Moreover, depending on the insulative nature of the dielectric material, electrons may be allowed to bore through, or jump across the dielectric material when enough energy is applied.

As used herein, “adjacent” refers to near or close sufficient to achieve a desired effect. Although direct physical contact is most common in the structures of the present invention, adjacent can broadly allow for spaced apart features.

As used herein, the singular forms “a,” and, “the” include plural referents unless the context clearly dictates otherwise.

As used herein, the term “substantially” refers to the complete or nearly complete extent or degree of an action, characteristic, property, state, structure, item, or result. For example, an object that is “substantially” enclosed would mean that the object is either completely enclosed or nearly completely enclosed. The exact allowable degree of deviation from absolute completeness may in some cases depend on the specific context. However, generally speaking the nearness of completion will be so as to have the same overall result as if absolute and total completion were obtained. The use of “substantially” is equally applicable when used in a negative connotation to refer to the complete or near complete lack of an action, characteristic, property, state, structure, item, or result. For example, a composition that is “substantially free of” particles would either completely lack particles, or so nearly completely lack particles that the effect would be the same as if it completely lacked particles. In other words, a composition that is “substantially free of” an ingredient or element may still actually contain such item as long as there is no measurable effect thereof.

As used herein, the term “about” is used to provide flexibility to a numerical range endpoint by providing that a given value may be “a little above” or “a little below” the endpoint.

As used herein, a plurality of items, structural elements, compositional elements, and/or materials may be presented in a common list for convenience. However, these lists should be construed as though each member of the list is individually identified as a separate and unique member. Thus, no individual member of such list should be construed as a de facto equivalent of any other member of the same list solely based on their presentation in a common group without indications to the contrary.

Concentrations, amounts, and other numerical data may be expressed or presented herein in a range format. It is to be understood that such a range format is used merely for convenience and brevity and thus should be interpreted flexibly to include not only the numerical values explicitly recited as the limits of the range, but also to include all the individual numerical values or sub-ranges encompassed within that range as if each numerical value and sub-range is explicitly recited. As an illustration, a numerical range of “about 1 to about 5” should be interpreted to include not only the explicitly recited values of about 1 to about 5, but also include individual values and sub-ranges within the indicated range. Thus, included in this numerical range are individual values such as 2, 3, and 4 and sub-ranges such as from 1-3, from 2-4, and from 3-5, etc., as well as 1, 2, 3, 4, and 5, individually. This same principle applies to ranges reciting only one numerical value as a minimum or a maximum. Furthermore, such an interpretation should apply regardless of the breadth of the range or the characteristics being described. Reference will now be made to the exemplary embodiments illustrated, and specific language will be used herein to describe the same. It will nevertheless be understood that no limitation of the scope of the technology is thereby intended. Additional features and advantages of the technology will be apparent from the detailed description which follows, taken in conjunction with the accompanying drawings, which together illustrate, by way of example, features of the technology.

With the general examples set forth in the Summary above, it is noted in the present disclosure that when describing the system, or the related devices or methods, individual or separate descriptions are considered applicable to one other, whether or not explicitly discussed in the context of a particular example or embodiment. For example, in discussing the nanofabrication per se, the device, system, and/or method embodiments are also included in such discussions, and vice versa.

Furthermore, various modifications and combinations can be derived from the present disclosure and illustrations, and as such, the following specific exemplary embodiments should not be considered limiting.

Local probes with integrated channels can be used to deliver gases near the probe tip with electrodes to produce large stationary and alternating electric fields to deposit and etch quantum dots on electronic materials including insulators, semiconductors and metals. The microfabrication and use of an atomic force microscopy (AFM)-tip-like device, or nanotorch, for use in microfabrication is described. This microfabrication device is capable of generating a very localized microplasma at a tip thereof. A submicron region near the tip provides a manufacturing environment where controlled direct-write nanofabrication can be performed. The microfabrication device can be fabricated using both surface and bulk micromachining techniques. More specific fabrication methods are described herein. After fabrication, the microfabrication device has been used successfully in semiconductor microfabrication. In specific examples, the microfabrication device has been used successfully in an O₂ environment at atmospheric conditions with an AC (alternating current) voltage of approximately 1000V. Microfabrication in O₂ environments and at atmospheric conditions reflects an improvement over many previous devices which use environments filled with a gas other O₂ and maintained at a pressure other than atmospheric pressure. Microfabrication using the microfabrication device and processes described below can result in less complex and less costly microfabrication. The device described herein can be a fabrication device capable of fabricating structures on a small scale. For example, the device is capable of microfabrication and nanofabrication, as well as fabrication at other scales. Reference to a specific scale of fabrication, such as microfabrication, is therefore included for exemplary purposes but is not limited thereto.

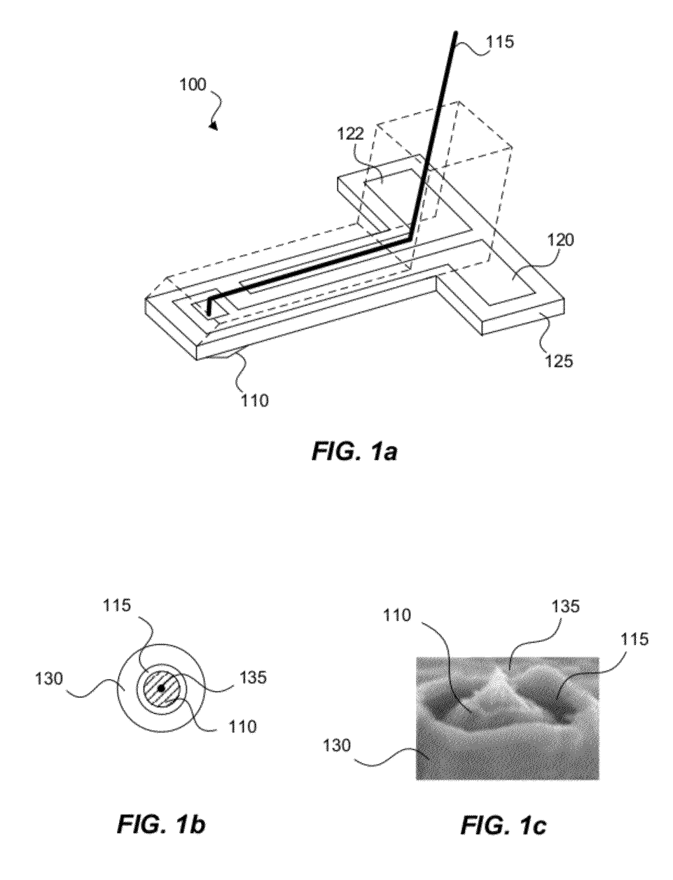

While much of the following disclosure describes an AFM tip or a type of AFM-tip-like device (also referred to herein as a “nanotorch”), the microfabrication device is not limited to AFM tip applications and may be used in place of tips other than AFM tips. In one aspect, a tip, such as a probe tip, can be functionalized by adding structure to or around the tip in order to enable the micro or nanofabrication described below. Accordingly, the nanotorch or microfabrication device can also be referred to as a “functionalized tip” device, or a device which includes a functionalized tip. The microfabrication device can generate a localized microplasma around a tip thereof to provide an energetic nano-manufacturing environment that can produce reactive gas species for etching and deposition. The entire microfabrication device structure can be suspended on a cantilever. The cantilever can be formed of any suitable material (e.g. silicon nitride). Reference will now be made to FIGS. 1a-1c. Referring first to FIG. 1a, a nanofabrication device 100 is shown which includes a conducting nanotip 110 and a gas microchannel 115 adjacent to the nanotip. The microchannel can be configured to deliver a gas to the nanotip. The nanofabrication device can include an electrode 120 in electronic communication with a power supply and the nanotip, the electrode being configured to deliver an electric charge from the power supply to the nanotip. The nanofabrication can include a substrate 125 upon which the conducting nanotip, the gas microchannel, and the electrode are arranged. In one aspect, the electrode can be the substrate or may be a metallic layer positioned over a non-conducting substrate. In the example shown in FIG. 1a, the device includes two electrode leads, a tip and a microchannel. One of the two electrode leads 120 is buried within the microchannel leading to the tip apex. The second electrode lead 122 runs on top of plasma ignited by DC (direct current) and AC (alternating current) signals. The device tip can be formed to focus deposition and decomposition conditions to a localized decomposition area. The specific shape, size and material of the device tip can affect the resolution of the localized deposition area. For example, the device tip can include an oxidation sharpened polysilicon tip coated with a thin layer of refractory Cr metal. The tip is protruding out of an interior of a microchannel through a small orifice which is formed at an end of the microchannel. A diameter of the orifice can vary depending on application, but in some examples is less than approximately 10 μm, or less than approximately 5 μm, or less than approximately 3 μm.

Referring to FIG. 1b, a bottom view of the nanotip 110 of the device 100 of FIG. 1a is shown. The nanofabrication device can include a metallic shield 130 substantially circumscribing the nanotip and defining the orifice. The metallic shield can be a ring electrode. The nanotip can include a conducting apex 135. FIG. 1c is a Scanning Electron Microscope (SEM) image of a side view of the tip shown in FIG. 1b. An annular microchannel exit can allow for relatively uniform distribution of gases about the nanotip. Although the annular microchannel 115 for gas delivery is shown, other microchannel configurations can be suitable. For example, a microchannel can have a single exit opening which is located adjacent to the nanotip 110 such as to a side of the nanotip.

The functionalized probe 100 shown in the schematic of FIG. 1a can be fabricated using standard silicon micro-machining techniques. The probe can be coated with harsh-environment and tribological SiC (silicon carbide) and diamond-like films, by bulk SiC and/or diamond tips or coatings, or by other suitable ceramic or corrosion resistant coatings. The tips can deposit, image, and etch materials to form nano-scale objects with precise dimensions. For example, the tips can be used to deposit, image, or etch materials with width and diameter down to about 10 nm, length down to about 10 nm-100 μm, and thickness down to about 10 nm-1 μm). The basic approach can be used with many gases and metal-organic precursors to deposit insulators, semiconductors, and a variety of metals, among other materials. Non-limiting examples of materials which can be deposited include silicon, silicon dioxide, silicon-germanium, silicon nitride, silicon carbide, silicon oxynitride, copper, aluminum, molybdenum, tantalum, titanium, nickel, tungsten, and the like. Corresponding precursors can be chosen as needed, but non-limiting examples of precursors include silane, dichlorosilane, oxygen, ammonia, nitrogen, metal chlorides, metal carbonyls, and the like. Dopants and other alloys can be optionally introduced into the deposited material via diffusion from the substrate and/or included within the source precursor gas. For example, phosphorus can be decomposed from phosphine gas and oxygen. Deposited materials can be polycrystalline, monocrystalline, or amorphous and can be epitaxial. Although the typical morphology can vary, structures can be produced such as quantum dots, nanofibers, nanowires, films, pads, and the like.

For the purpose of illustrating the principles of this nanodeposition device, silane and argon gases (SiH₄/Ar) can be used to deposit silicon quantum dots. Misplaced deposited material can be subsequently removed. For example, etching can be accomplished using 20-50 eV Ar ions generated near the probe tip. These ions can be used directly in an “ion milling” mode and can also be used to excite surface-adsorbed SF₆ molecules on the sample to perform reactive ion etching to correct line widths and pattern lines for device formation. This can further augment resolution of the deposition patterns which can be achieved.

Nanotips 110 with micro-channels 115 and integrated electrodes 120, 122 can be fabricated to deliver and excite gas molecules directly under the tip apex as schematically shown in FIG. 1a. A tip with microchannels and electrodes is referred to herein as a “functionalized” tip or probe. The electrodes on the tip enable more precise deposition and etching of materials as well as enable deposition/etching over insulating (oxide or nitride) substrates. For example, these functionalized probes can be characterized and used with a thermo-microscope AFM setup to deposit/etch silicon nanowires on silicon dioxide. Moreover, deposition and fabrication of probes with integrated piezoelectric and thermal actuators can be provided as will be described in further detail below.

Piezoelectric actuation can be used for y-z-deflections and piezoresistive sensing for tip-sample interactions and for sensing and actuating movement of a direction of the nanotip with respect to the sample. The piezoresistive sensing can operate at ranges of approximately 0.5 to 1.5 nm stand off sensing, or more specifically at approximately 1 nm stand off sensing. These actuators and sensors can be integrated with the probe to enable multi-axis probe control of a multi-tip array with on-board hybrid electronics. For example, a 30-tip array with integrated actuators, sensors and on-board electronics can provide for deposition of large areas and/or multiple deposition materials. The piezoresistor position sensors produce current changes on the order of a few microamperes and can be shielded from relatively large signals applied to the piezoelectric actuators (approximately 10-15 volts and a low current of less than a few tens of microamperes current) and deposition/etching electrodes (approximately 20-100 volts and a few tens of microamperes current). A multi-tip array can include an array of microchannels, where at least one microchannel is associated with each tip in the multi-tip array. In one aspect, an individual tip can have multiple microchannels associated therewith to deliver at least two different gases to the individual tip. The ability to individually deflect tips in y-z directions can allow for minute adjustments to deposition locations. In connection with moving the substrate a wide variety of deposition patterns can be achieved. The inherent resolution limitation provided by movement of a substrate support mechanism can be augmented and increased by finer deflection control of individual cantilevered and supported tips.

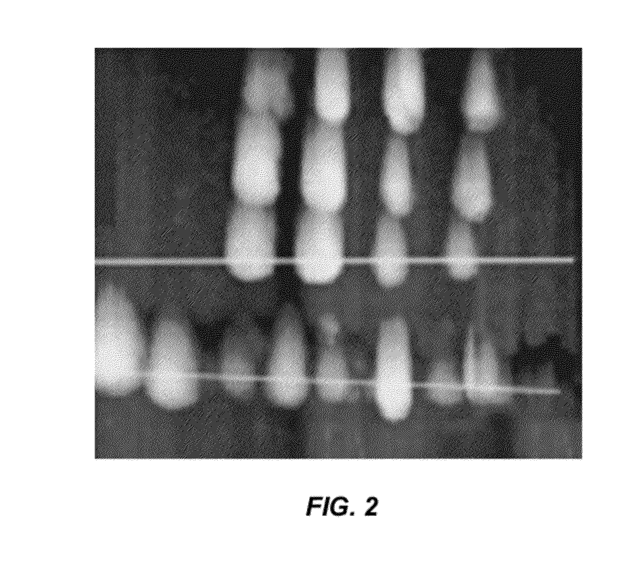

Local probes can be used to deposit and modify conducting samples or to deposit nano-ink and perform nano-lithography. In one example, light emission spectra was recorded from a scanning tunneling tip in the presence of argon. This experiment demonstrates that currents passing through very narrow gaps can be used to ionize gases. In another experiment shown in the image of FIG. 2, germanium was deposited over silicon using germane gas to demonstrate the use of a probe to ionize gases and to deposit the resulting ions in the form of a patch over a conducting sample. With the functionalized local probes described herein, depositing, etching and imaging nano-scale structures on insulating, semiconducting, and conducting substrates using functionalized AFM probes is enabled. As described above, two or more electrodes on the probe or microfabrication device can be used to perform deposition and etching tasks. These electrodes on the tip eliminate the need for a conducting substrate. As such, patterned deposition can be provided on a wide variety of substrates including, but not limited to, metals, polymers, ceramics, carbon fiber composites, and a variety of other materials. This approach can be used with a variety of metal-organic gases for depositing many important semiconductors including GaN (from gallium triethyl and triethyl amine), SiC (from trimethylsilane and methane), and diamond (from acetylyne), metals such as nickel (from nickelocene), and gold (from gold monochloride), oxides including SiO₂ (from trimethyl silane and oxygen), Al₂O₃ (from aluminum isoproxide and oxygen), hafnium oxide, zinc-oxide, aluminum nitride, and other materials from appropriate precursors can be deposited.

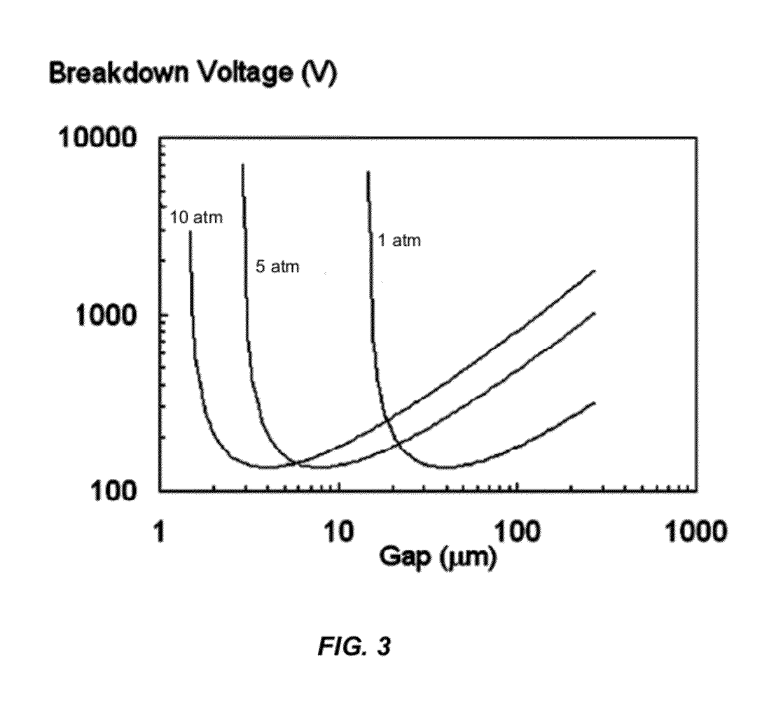

The electrodes of the functionalized AFM tip with a ˜1 μm gap produce a highly non-uniform electric field near the pointed and sharp (˜10 nm curvature) apex. Extensive research using pointed electrodes (˜1-25 μm curvature) but much larger gaps of 50-100 μm has shown that different regimes of discharge and gas excitation exist. The DC breakdown of gases is illustrated by a Paschen curve in FIG. 3 that shifts to lower fields at high excitation frequencies (optimum at around 3-50 MHz depending on the tip geometry), or when the voltage is pulsed, or when an appropriate optical illumination (usually UV) is used, or by radio-active ionization. The breakdown of gas results in the generation of positive and negative charges in the gas that are commonly referred to as “plasma”. The initial breakdown regime that occurs at low current densities but high fields is called “self-sustained Townsend discharge” and is followed by a second regime called “glow discharge” where the current is high but the gap voltage drops due to high gas conductivity. In this regime a “feedback” involving electrons, ions, and photons from the breakdown in the gas occurs that sustains the current flow in the gap. This regime is followed by “corona discharge,” then by “spark discharge,” and finally by “arc discharge.” In the arc discharge, the gap voltage is rather low and the current is relatively high, leading to rapid evaporation of the electrode material in some cases. The spark breakdown is nearly the opposite where the voltage is high and the current is low. Glow discharges are relatively “cold” breakdowns, whereas coronas are relatively “hot” breakdowns. In a pulsed mode, a new mode of breakdown is enabled called a “streamer” regime which is a much faster process and is based on the notion that a thin plasma channel can travel by ionizing the gas in front of a charged head of the plasma channel by the strong field of the head.

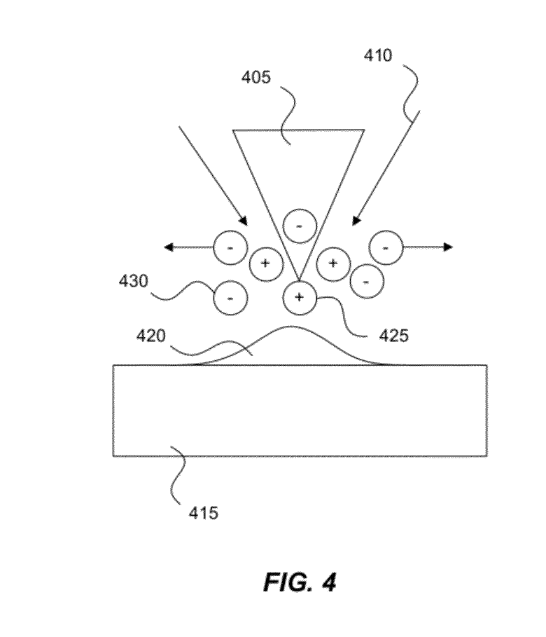

Both steady-state and transient plasmas can be used to deposit and etch materials near the tip. Transient plasmas can achieve smaller deposition/etch spots, but may occur randomly. To reduce randomness, the AFM tip and associated electrodes can be designed with reduced symmetry to favor transient plasma formation in a well-defined region. FIG. 4 schematically shows how ionization near the tip in combination with gas flow and tip geometry can be used to deposit/etch with high spatial resolution. For example, gases 410 are delivered adjacent to a negatively charged nanotip 405. The charge of the nanotip causes the gases to excite and decompose into positively 425 and negatively 430 charged components. The positively charged components form a solid product 420 on a substrate 415 and the negatively charged components are repelled by the charge of the tip.

Due to a small gap size of a few micrometers, the present device works in the “near-field” or the “circuit” limit even when the electrodes are excited with millimeter waves of 100-300 GHz frequencies. Thus, the classical models of plasma do not appear to apply. As soon as the gas molecules are ionized, the molecules are separated and traverse the gap region as described above. The impedance of the AFM electrodes is capacitive before the gas breakdown and inductive afterwards. By adjusting the impedance matching circuit during the gas breakdown, an efficient scheme can be devised to transfer maximum energy to dissociate gas molecules near the electrodes. The impedance matching can be accomplished using a manual technique by monitoring the reflected wave amplitude and minimizing the reflected wave to maximize energy transfer. The impedance matching can also be accomplished automatically using a variable capacitor device controlled by a microcontroller. A combination of gas pressure, flow rates, and ionization parameters can be used to deposit and etch within the desired spatial resolutions. For example, very high quality dots can be deposited using a slow deposition rate and careful control of ionic species near the dot during deposition. High flow rates use a larger electronic current, which leads to high deposition rates, while lower flow rates are desirable for low deposition rates. Environmental parameters, such as humidity, and contaminants, such hydrocarbons, CO₂, and the like may affect growth more substantially at low deposition rates. As a result, carrier gases can be used to control the growth environment.

To increase reproducible and high-quality deposition and etching of nanoparticles, the starting surface can be cleaned. Moisture and hydrocarbons are common contamination layers on electronic materials in laboratory environments. A sample can be cleaned immediately before an AFM-assisted nanofabrication step by using standard degreasing and decontamination procedures followed by heating the sample to approximately 300° C. in high-purity argon flow for about 30 minutes to remove most of the contaminants. The functionalized probe can be used in an etching mode to locally etch or clean the sample before a deposition step. These steps are compatible with CMOS (complementary metal-oxide-semiconductor) and silicon-based integrated circuits and do not adversely affect electronic properties of any existing devices on the sample.

In a specific example, controlled deposition of silicon quantum dots can be performed using silane and argon (SiH₄+Ar). Silane can be dissociated near the AFM apex by the strong field generated between the tip electrodes and the electrons injected by the tunneling current. Extensive literature has been devoted to species generated in SiH₄ discharge. SiH₄ has a heat of formation of 34.3 J/mol and a Si—H bond distance of 0.15 nm. SiH₃ and SiH₂ radicals are important precursors for silicon deposition. The SiH₃—H, SiH₂—H, SiH—H, and Si—H bond energies are respectively 3.9 eV, 3.0 eV, 3.4 eV, and 3.0 eV. Rate constants for formation of these radicals have also been extensively studied. Most existing models of silicon deposition from SiH₄ (with hydrogen or argon carrier gases) are based on processes that occur in large reactors with high and uniform substrate temperatures (such as 700-1000° C., for example) and large ion kinetic energies. In contrast, the entire reactor for the present technology is located underneath the tip and many parameters are highly non-uniform. In the narrow gap between the AFM electrodes the primary processes involving electron impact reactions dominate, whereas neutral-neutral and positive ion-neutral reactions are seemingly less important.

Mass spectrometry and/or ion mobility spectroscopy can be performed to analyze reaction products generated by the functionalized AFM probe as a function of pressure, excitation voltage and carrier gas ratio. To ensure compatibility with existing CMOS or other electronics on the sample, external sources of energy that are used in addition to the electrical excitation of the electrodes are typically limited to include energy sources such as photo-excitation, illumination with an external (low power˜mW) microwave, and moderate heating of the substrate, which heating is generally limited at a high end to around 400° C. A UV (ultraviolet) fiber optic illumination source, moderate substrate heating, and illumination using an external low-power microwave source, in addition to the excitation voltage applied to the electrodes, can be used together, for example. The conical AFM tip can be used as a concentrator antenna to focus energy to the apex region to deposit very high quality silicon quantum dots in a very controlled manner Post deposition rapid thermal annealing can also be used to further improve quantum dot properties.

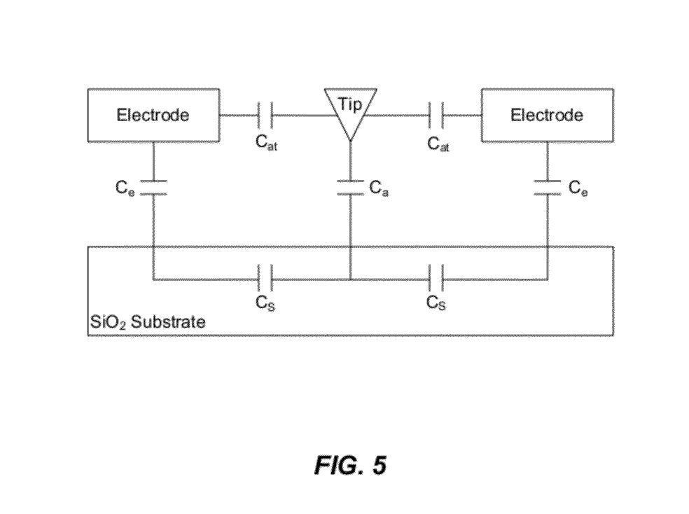

In another example, argon ions (Ar⁺) can be generated near the functionalized AFM tip in a similar fashion to SiH₄ radicals discussed above. The Ar⁺ ions can be used to physically remove deposited silicon to correct the quantum dot dimensions. Other gases such as He (helium), Xe (xenon), and nitrogen can also be used for plasma generation. This “ion milling” mode of material removal is non-reactive and can be used to remove semiconductor materials, as well as oxide and metal materials. To direct an appreciable component of the kinetic energy of the Ar⁺ ions toward the insulating substrate, an evanescent field profile near the tip will preferably have a large component perpendicular to the insulating substrate. This condition can be achieved by carefully maximizing the capacitive coupling of the probe electrodes through the insulating substrate as shown in the finite element model of FIG. 5. FIG. 5 illustrates capacitive coupling Cₐₜ with the Argon between the Electrodes and the Tip, capacitive coupling Cₐ with the Argon between the tip and the SiO₂ substrate, capacitive coupling Cₑ between the electrodes and the substrate, and capacitive coupling C_{S} between the electrodes and tip within the substrate. The Ar⁺ can also be used to activate surface-adsorbed SF₆ molecules to reactively etch materials to achieve higher etch rates if desired.

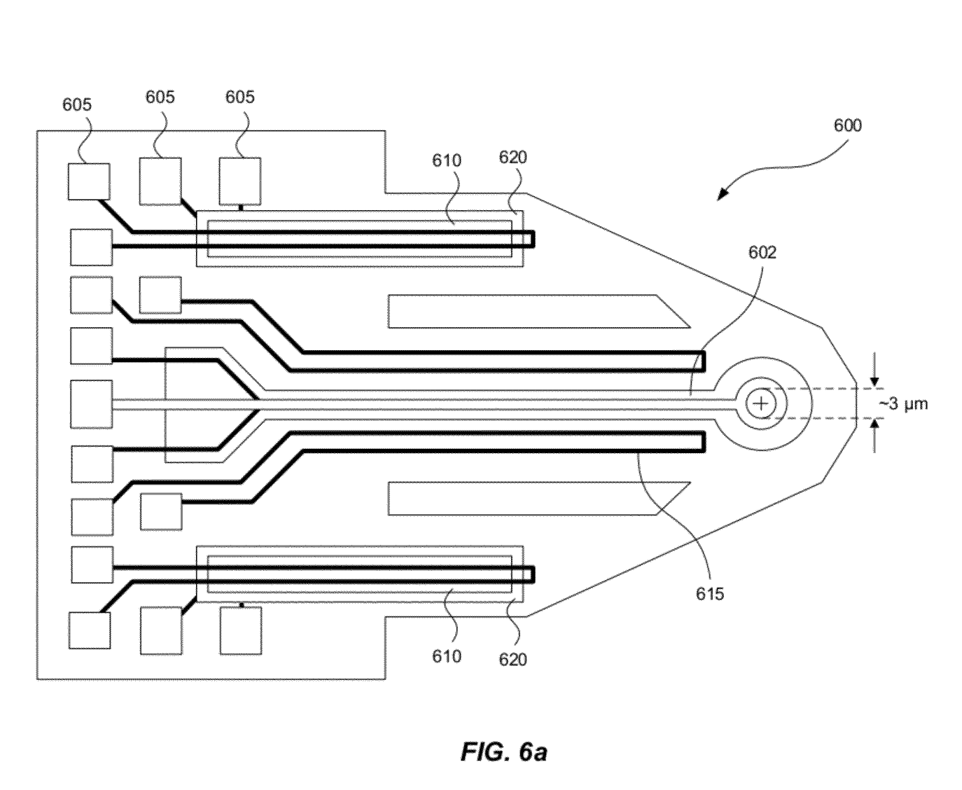

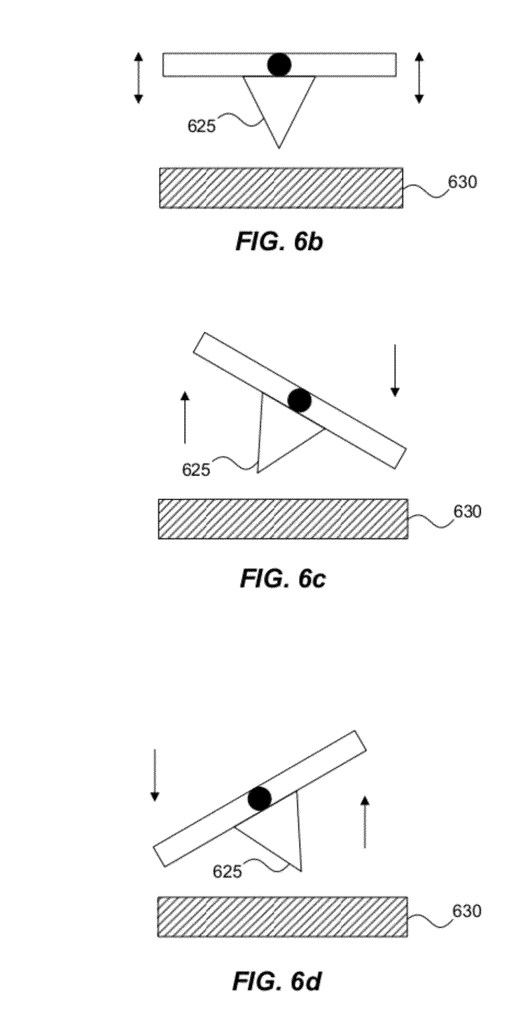

Referring now to FIG. 6a, a functionalized AFM probe 600 with integrated electrodes 605, sensors and actuators is schematically shown. The cantilevered arm length is shorted merely for convenience in illustration. A fabrication process of the probe can be carried out using conventional lithography techniques and, in one example, consists of three different processes of beam formation using bulk micromachining, electrode formation, and channel 602 formation. The fabrication process will be described in further detail below. Piezoresistive position sensors 610, 615 and piezoelectric actuators 620 can be used for y-z directed actuations as shown in FIGS. 6b-6d. For example, FIG. 6b illustrates use of the sensors and actuators substantially simultaneously in a common direction on both sides of the tip 625 to move the device up and down uniformly with respect to a substrate 630 or sample. FIGS. 6c-6d illustrate use of the sensors and actuators substantially simultaneously on both sides of the tip in substantially opposite directions to tilt or turn the device one direction or another with respect to the substrate.

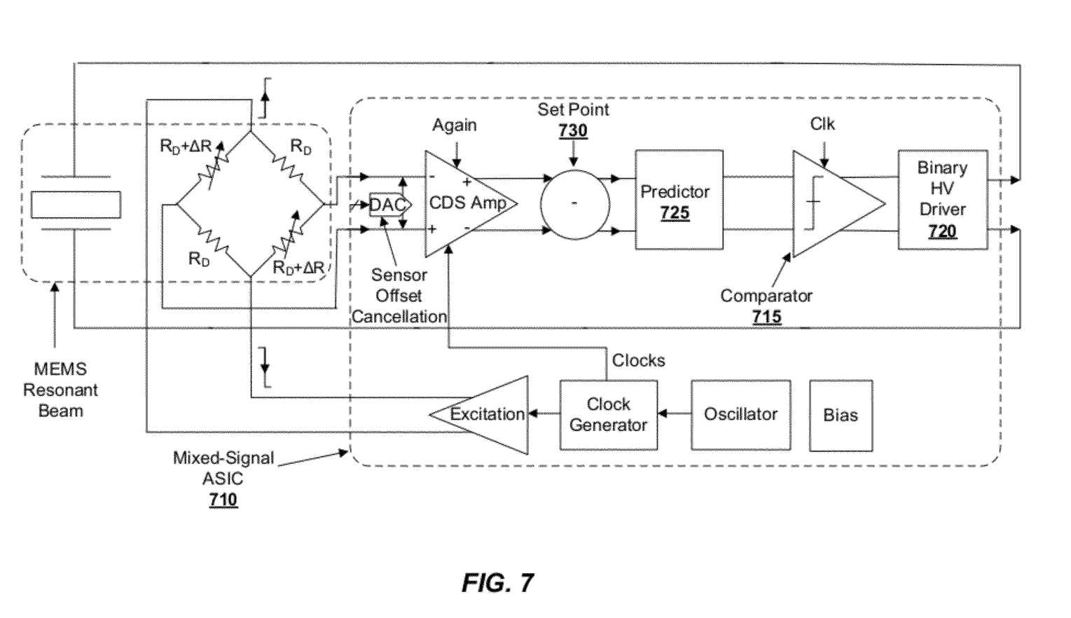

Referring now to FIG. 7, a 4-channel ASIC (application-specific integrated circuit) 710 can provide sensor/actuation/control electronics for the microfabrication device. The ASIC can similarly provide a convenient interface to a computer which can host a process or control system. In the example of the 30-tip system described above, the system can be built using a single PCB (printed circuit board) with eight of the ASICs. The ASIC can be formed using a conventional 1.5-μm mixed-signal CMOS process with lightly doped drain (LDD) transistors for high-voltage operation using n-well and p-base layers as drain junctions and second poly layer as the gate.

To address control of tip deflection using the electronics, a mixed-signal approach can be provided using a binary (digital) output driver using pulse-density modulation (PDM). PDM can be readily implemented in mixed-signal CMOS technology in the form of a sigma-delta tracking loop, as illustrated in FIG. 7. The comparator 715 can be clocked at about 100 times a resonance frequency, such as at 5 MHz for example, and the result of the comparison can be used to actuate the high-voltage binary driver 720 in the desired direction to maintain the set point 730. The high Q (resonator quality factor) of the cantilever beam (˜100) can act as a two-pole filter that destabilizes the sigma-delta tracking loop. As in a linear analog approach, however, the loop can be stabilized by inserting a zero in the frequency response (i.e., a differential predictor 725) prior to the comparator, as illustrated in FIG. 7. The error signal generated at any given x-y location is proportional to the height variations at that location and can be used to construct the topography image of the sample. Onboard electronics can be provided to generate voltage pulses for deposition/etching of quantum dots. These pulses can be synchronized with the sense/control/imaging electronics using a computer.

Controlled deposition and etching of silicon quantum dots over SiO₂ can be performed to produce 50+/−5 nm and 80+/−8 nm diameters dots (1/min) with nominal thickness of ˜10 nm located at 50 nm from a land mark using the AFM-compatible probes with integrated electrodes and micro-channels. The tip stand-off distance can be sensed with a resolution of 20 nm of the surface and tip height (7 μm) deterioration less than 10% with tip radius (10 nm) deterioration less than 20% after 100 operations. Controlled deposition, etching and imaging of silicon quantum dots over SiO₂ using 5-probe arrays has been demonstrated to produce twenty five dots (5/min/tip) with diameters ranging from 60+/−2 nm to 100+/−3 nm with 10 nm increments and with thicknesses ranging from 10+/−0.3 nm to 30+/−0.9 nm with 5 nm increments. These dots can be located within 25 nm distance from a reference landmark. The tip stand-off distances can be sensed with 10 nm resolution while tip height (7 μm) deterioration can be less than 5% and tip radius (10 nm) deterioration can be less than 10% after 1000 operations.

The underlying mechanics of the deposition techniques will now be described. The probe structure includes a conical tip with a conducting apex that is co-axially located with an electrode ring at the bottom of the tip's insulating outer region. A channel etched between the inner cone and the outer insulator introduces and delivers gases to the region between the probe apex and a sample. A static and or alternating potential between the apex and the tip electrode ring causes dissociation, and in some cases ionization, of the gas molecules near the tip, leading to deposition of solid material over the substrate under the probe apex.

Gas mean free path in 1 atmosphere pressure at room temperature is around 0.1 μm and in examples where the probe channel cross-section is around a few μm², the flow rates may be low and the gas in the channel may be pressure driven. The ionization products near the tip will be removed by a slight vacuum that will also help to drive the gas molecules through the narrow channels.

In the gas-phase deposition technique, the probe can be used as a nano plasma torch, or nanotorch, by using an etching gas instead of a metal-organic gas. Some non-exhaustive examples of etching gases include oxygen, fluorine, chlorine, and the like, as well as gases which are oxygenated, fluorinated, chlorinated, etc. Two or more channels around the tip can be used to flow two or more types of different gases near the tip for deposition and subsequent etching. In this case, the ionizing source will be the cold cathode tip or ionized gases can be introduced to the channel and guided by the electrode fields. In liquid-phase deposition, the tip can be used as an electrochemical probe where the tip polarity is reversed to etch and reversed again to deposit. Etching liquid can be introduced using one of the channels while the other channel carries the deposition liquid. In colloid-phase deposition, the tip polarity can be reversed to remove the nanoparticles by attracting the particles to the tip.

The tip can be used as a nano-plasma torch, an electron source, or electrostatic tweezers depending on how the tip is operated. In each of these examples the probe can be used to etch the deposited materials or nano-particles.

Microplasmas are miniaturized glow discharges that operate at high pressures (>1 atm) and small dimensional scales (<100 microns). Microplasmas are typically formed between two metal electrodes, a cathode with a pin-hole (d<100 microns) and an arbitrarily shaped anode. As a result of the high electric fields created by the cathode cavity, microplasmas contain large concentrations of high-energy electrons (tunneling through the colt cathode tip, etc.) which allow rapid disassociation of gases. Other electron sources for gas ionization, such as implanted radioactive materials and the like, such as those used in smoke detectors, can also be used. Microplasmas are well-suited to non-lithographic applications in materials processing. Since microplasmas can be operated over small dimensions, an approach to etching (or deposition) would be to use a stencil mask which transfers the pattern directly. Microplasmas in flexible copper-polyimide structures have been used to pattern silicon using CF₄/Ar chemistry. Further scaling down of the plasma source can enable direct patterning of nanoscale structures on substrates.

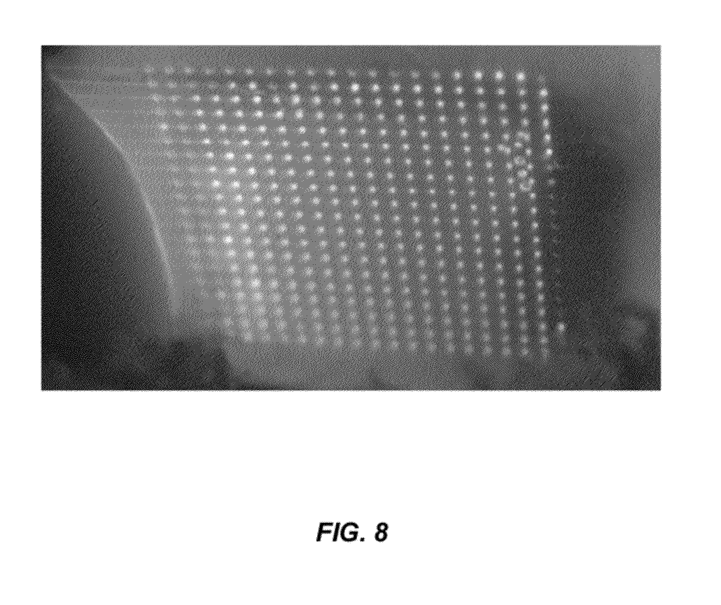

In FIG. 8, a photo of a microplasma array is shown made-up of 20×20 100 μm diameter holes. The gas flows through channels with a diameter of 20 μm. As smaller scales are approached, these plasmas allow micro- and nanostructured materials to be created directly on substrates. Thus, microplasma operation can be combined with AFM technology to directly grow or deposit nanostructures on various substrates. Towards this end, a microplasma source can be designed and fabricated that operates on a significantly smaller scale, such as less than 100 nm in dimension. A single microplasma source can be used to etch and/or deposit nanostructures on substrates. The microplasma source can be scaled down to less than 100 nm to allow direct synthesis of metal or semiconductor nanostructures. The properties of the microplasma source can be a function of several operating parameters, including but not limited to: plasma power, gas flow rate, pressure, and gap between the plasma and substrate. Single structures with dimensions less than 10 nm using a single microplasma source can be obtained, depending on the parameters chosen.

Microplasma arrays can be fabricated by microfabrication techniques that allow the device geometry to be modified easily. Ordered nanostructure arrays can be grown on substrates in parallel. In addition, the gas flows in the microplasma device can be independently controlled to allow the growth conditions in individual plasmas to be varied.

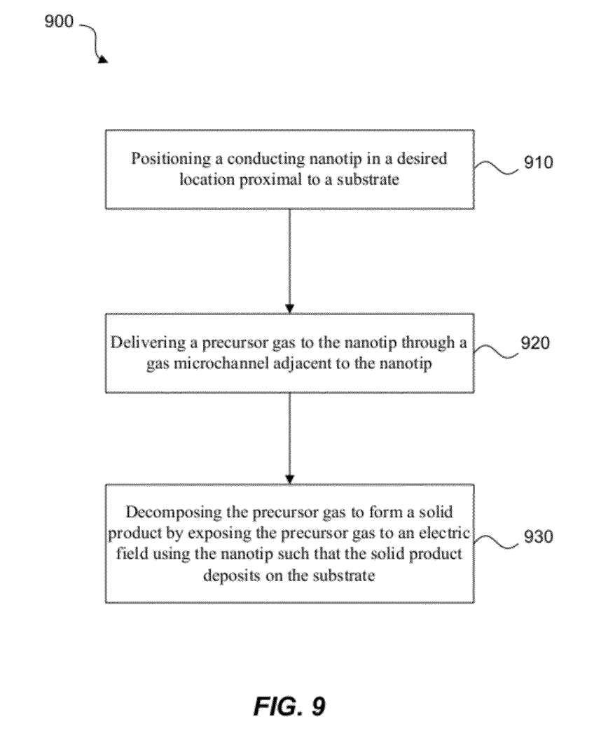

Referring to FIG. 9, a flow diagram of a method 900 of nanofabrication is illustrated. The method can include positioning 910 a conducting nanotip in a desired location proximal to a substrate. The desired location can be the location where etching, deposition, or imaging is desired. The location proximal to the substrate can be sufficient to enable the capacitive coupling described above, which may vary depending on operating conditions and materials. The method can further include delivering 920 a precursor gas to the nanotip through a gas microchannel adjacent to the nanotip and decomposing 930 the precursor gas to form a solid product by exposing the precursor gas to an electric field using the nanotip such that the solid product deposits on the substrate.

As has been described, the substrate can be an insulating substrate. The step of positioning 910 can therefore include positioning the conducting nanotip in the desired location proximal to the insulating substrate. The step of decomposing can include decomposing the gas over the insulating substrate.

In a variation or alternative to the method 900, or as a corollary to the method, the nanotip can be positioned in a location proximal to the solid product. A same or different precursor gas can be delivered to the nanotip through the gas microchannel. The precursor gas can be decomposed into argon ions by exposing the same or different precursor gas to an electric field using the nanotip, and the solid product on the insulating substrate can be etched using the argon ions. Ions other than argon ions may also be used in the etching process.

In one aspect, reversing a polarity of the electric field will switch the device or method between causing the solid product to be deposited on the substrate and etching the solid product on the substrate.

Where the device includes an array of nanotips and gas-delivering microchannels, the method 900 can include positioning the array of nanotips, delivering the precursor gas to the array of nanotips through the array of gas microchannels adjacent to the array of nanotips, and decomposing the precursor gas using the array of nanotips (or rather the electric field generated by or near the array of nanotips).

The method 900 can include multiple common or different precursor gases substantially simultaneously either to different nanotips each being associated with a respective microchannel or to a common nanotip being associated with a plurality of microchannels which exit to deliver precursor gases to a common nanotip.

The method 900 can include sensing and actuating movement of a direction of the nanotip in a plurality of directions using a piezoresistive position sensor and a piezoelectric actuator, which can be integrally formed with the nanofabrication device.

Also, the method 900 can include decomposing comprised of transient plasma discharge decomposition as has been described above in relation to FIG. 8.

A more specific example of gas phase deposition will now be described. To calculate the electric field, current and the speed of deposition, a cylinder underneath the probe that approximately encloses the reaction region can be selected. At one atmosphere (0.1 MPa) and at 50° C., the volume enclosed by a cylinder of 100 Å height and 100 Å diameter, will contain approximately 18 atoms. Using a moderate voltage of approximately 5 volts applied across the 100 Å gap, an electric field is produced of approximately 5×10⁶ V/cm. (The breakdown field of air under these conditions is marginally higher than 6×10⁶ V/cm). Pre-breakdown tunneling current flow may be approximately 0.3 nA. An electrostatic attraction exists between the tip and the substrate which may cause clamping, but this clamping can be prevented using commonly employed feedback mechanisms known in AFM technologies. The electric field generated will draw nearby gas molecules into the tip-ring electrode gap region due to a dipolar interaction. Once the gas molecule is situated in the high-field region near the tip, the tunneling electronic current is modified and assisted through the electronic transitions in the localized gas molecule. This apex-molecule-electrode double junction provides a mechanism to “pump” electrons into the gas molecule that, in addition to decomposing the molecule, may ionize the gas molecule under proper conditions. The power dissipated in the gap is approximately 5×0.1×10⁻⁹=500 pW. This power will increase the temperature of the gap (mainly the electrons in the gap) to in excess of a few thousand Kelvin locally in 1 ns. The temperature thus becomes sufficient to decompose the precursor gas. Using the appropriate tip-substrate field polarity, the metallic ion can be directly deposited on various substrates.

Assuming that roughly 10 atoms are present at any given moment under the tip in the reaction region, and assuming that decomposition of the atoms takes approximately 1 nanosecond, the deposition rate would be 10 atoms per nanosecond or 10¹⁰ atoms per second. A strip of 100 Å width and 1 μm length with 100 Å thickness contains ≈10⁹ atoms (assuming 5 Å lattice constant) and would thus be deposited in approximately 0.1 second.

Metal substrates, such as Mo(CO)₆ and W(CO)₆ start to decompose at about 150° C. Mo (molybdenum) and W (tungsten) have been deposited by thermal decomposition of the Mo or W vapor to produce the metal (Mo or W) and carbon monoxide (CO). If the deposition temperature is low around 250° C., the films become highly contaminated with CO. However, at temperatures of about 500° C. the process produces very pure deposits. The temperature is equivalent to a kinetic energy 0.04 eV. If nanoprobes are used with a top voltage of 5V (5×10⁶V/cm gradient), there is more than sufficient energy to decompose the compounds completely.

The metal atoms are attracted to the substrate by van der Waals forces (dipolar interactions) or by Columbic forces if the atoms are ionized. Because generating a positive charge on the metal is typically easier than generating a negative charge, the probe tip will generally be positively charged to “extract” electrons from electrically (dipolar) trapped gas molecules near the tip. The carrier gas (e.g., argon) and the metal atom are both charged and attracted to the negative substrate, decomposing more metal carbonyl molecules on the way toward the substrate.

The vapor pressures of metal carbonyls may be low at room temperature but are still much higher than those of the other compounds studied for CVD (chemical vapor deposition). Mo(CO)₆ boils at 153° C., at which temperature the Mo(CO)₆ decomposes slowly. Deposition can be run at 100° C. with a vapor pressure of several hundred mm for the compound. W(CO)₆ boils at 175° C. and will have a slightly lower vapor pressure than Mo(CO)₆ at any given temperature. However, both Mo(CO)₆ and W(CO)₆ compounds are volatile enough to achieve rapid deposition of the metal under the conditions generated under the probe's apex.

A similar principle can be applied to generate metal oxides, except that oxygen may be used to prevent partial reduction of the oxide or the formation of silicon carbide. SiO₂ can be made from tetramethoxy silane (bp=122° C.), trimethyl silane (bp=6.7° C.) or dimethyl silane (bp=−20° C.). Similarly, Al₂O₃ can be made using aluminum isoproxide (bp=140.5° C. at 8 mm pressure) in the presence of oxygen. This is safer than using trimethyl aluminum (bp=20° C.), which is pyrophoric and can react spontaneously with O₂. The advantage of using the metal alcoholates is that the metal alcoholates are completely stable in the presence of oxygen at room temperature. However, the organic fragments generated under the probe tip can react rapidly to H₂O and CO₂, leaving SiO₂ or Al₂O₃ as the remaining non-volatile product. The probe energy can be adjusted so that the effective temperature of the fragments will be approximately 1000 K, or high enough that all organic material is oxidized (by injecting tunneling ions) while maintaining stability of the oxides.

Many semiconductors can be deposited. Some specific examples include GaN (gallium nitride), Si (silicon), SiC (silicon carbide), and Graphene. However, many other semiconductor materials can also be deposited. GaN can be generated from gallium triethyl and an amino (such as ammonia) precursor. If this forms a stable complex that deposits on all surfaces, triethyl amine can be used. Alternatively, gallium chloride (bp=201.3° C.) can be used as a precursor and which is easier to manage. Silicon and SiC can be deposited using silane and trimethylsilane. Graphene can be deposited using methane. Nickel quantum dots can be deposited first as catalysts. The current generated near the apex is billions of times larger than the number of molecules under the probe tip. At 1-10 eV energy and in the presence of ˜1 nA tunneling electronic current, molecules can be heated up to a few thousand Kelvin. The molecules can be effectively fragmented with individual atoms and ions. The ions are attracted to the substrate, neutralized and quenched to give the final deposited layer. The effective temperature can be adjusted so that the semiconductor fragments are stable and can be deposited stably. Outside the active area, any residual fragments are diluted sufficiently rapidly that there is little or no contamination.

Non-limiting examples of other semiconductor materials can include group IV materials, compounds and alloys comprised of materials from groups II and VI, compounds and alloys comprised of materials from groups III and V, and combinations thereof. More specifically, exemplary group IV materials can include silicon, carbon (e.g. diamond), germanium, and combinations thereof. Various exemplary combinations of group IV materials can include silicon carbide (SiC) and silicon germanium (SiGe). In one specific aspect, the semiconductor material can be or include silicon. Exemplary silicon materials can include amorphous silicon (a-Si), microcrystalline silicon, multicrystalline silicon, and monocrystalline silicon, as well as other crystal types. In another aspect, the semiconductor material can include at least one of silicon, carbon, germanium, aluminum nitride, gallium nitride, indium gallium arsenide, aluminum gallium arsenide, and combinations thereof.

Exemplary combinations of group II-VI materials can include cadmium selenide (CdSe), cadmium sulfide (CdS), cadmium telluride (CdTe), zinc oxide (ZnO), zinc selenide (ZnSe), zinc sulfide (ZnS), zinc telluride (ZnTe), cadmium zinc telluride (CdZnTe, CZT), mercury cadmium telluride (HgCdTe), mercury zinc telluride (HgZnTe), mercury zinc selenide (HgZnSe), and combinations thereof.

Exemplary combinations of group III-V materials can include aluminum antimonide (AlSb), aluminum arsenide (AlAs), aluminum nitride (AlN), aluminum phosphide (AlP), boron nitride (BN), boron phosphide (BP), boron arsenide (BAs), gallium antimonide (GaSb), gallium arsenide (GaAs), gallium nitride (GaN), gallium phosphide (GaP), indium antimonide (InSb), indium arsenide (InAs), indium nitride (InN), indium phosphide (InP), aluminum gallium arsenide (AlGaAs, AlxGa1-xAs), indium gallium arsenide (InGaAs, InxGa1-xAs), indium gallium phosphide (InGaP), aluminum indium arsenide (AlInAs), aluminum indium antimonide (AlInSb), gallium arsenide nitride (GaAsN), gallium arsenide phosphide (GaAsP), aluminum gallium nitride (AlGaN), aluminum gallium phosphide (AlGaP), indium gallium nitride (InGaN), indium arsenide antimonide (InAsSb), indium gallium antimonide (InGaSb), aluminum gallium indium phosphide (AlGaInP), aluminum gallium arsenide phosphide (AlGaAsP), indium gallium arsenide phosphide (InGaAsP), aluminum indium arsenide phosphide (AlInAsP), aluminum gallium arsenide nitride (AlGaAsN), indium gallium arsenide nitride (InGaAsN), indium aluminum arsenide nitride (InAlAsN), gallium arsenide antimonide nitride (GaAsSbN), gallium indium nitride arsenide antimonide (GaInNAsSb), gallium indium arsenide antimonide phosphide (GaInAsSbP), and combinations thereof.

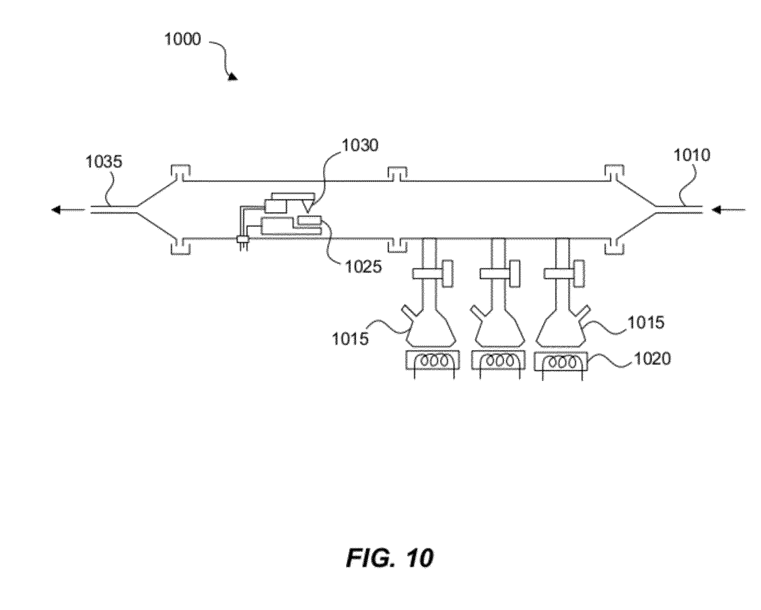

A high vacuum chamber 1000, as depicted in FIG. 10, can be used to examine the conditions for depositing materials from precursor gases using field and electron-assisted decomposition and ionization of gas molecules. In FIG. 10, a carrier gas inlet enables the carrier gas to enter the vacuum chamber. One or more same or different gases 1015 can be used separately or in combination with the gas from the carrier gas inlet, and may be heated using heaters 1020 before entering the vacuum chamber. The influx of the gas(es) can provide a sublimation stage in which sufficient temperatures and pressures cause a substance to endothermically transition from a solid phase to a gas phase without an intermediate liquid phase. An x-y stage 1025 with a heater can be provided for a deposition stage of the process over which the nanotip can operate to deposit, etch, or image a sample. Gases can exit through the outlet, which may be a vacuum-type outlet.

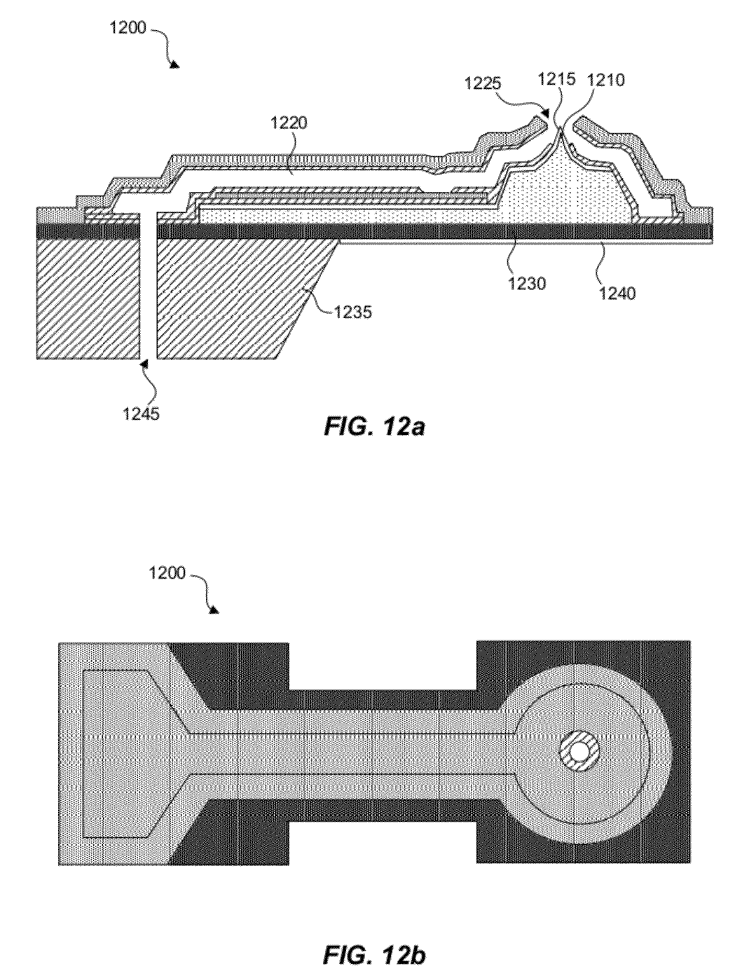

Because some precursors may be unstable in air or flammable, neutral carrier gases and a moderately low vacuum can be used to remove reactive gas species and reduce exposure to ambient oxygen. This can be easily accomplished using a “global” vacuum chamber 1200 schematically shown in FIG. 12 where scanning probes 1210 are enclosed in micro-chambers 1215 with gas supply lines 1220. Arrows indicate the flow of gas into and out of the micro-chambers. Micro-pumps and valves are all fabricated on silicon using MEMS (microelectromechanical systems) technology. Parallel local probes deposit patches of semiconductors, metals, and insulators over the substrate 1225. The probes with two-axis control combined with linear motion of the substrate underneath the probes (using a linear motor) have sufficient degrees of freedom to deposit quantum dots, tubes, wires, and the like.

The semiconductor materials of the present disclosure can be made using a variety of manufacturing processes. In some cases the manufacturing procedures can affect the efficiency of the device, and may be taken into account in achieving a desired result. Exemplary manufacturing processes can include Czochralski (Cz) processes, magnetic Czochralski (mCz) processes, Float Zone (FZ) processes, epitaxial growth or deposition processes, and the like. It is contemplated that the semiconductor materials used in the present invention can be a combination of monocrystalline material with epitaxially grown layers formed thereon.

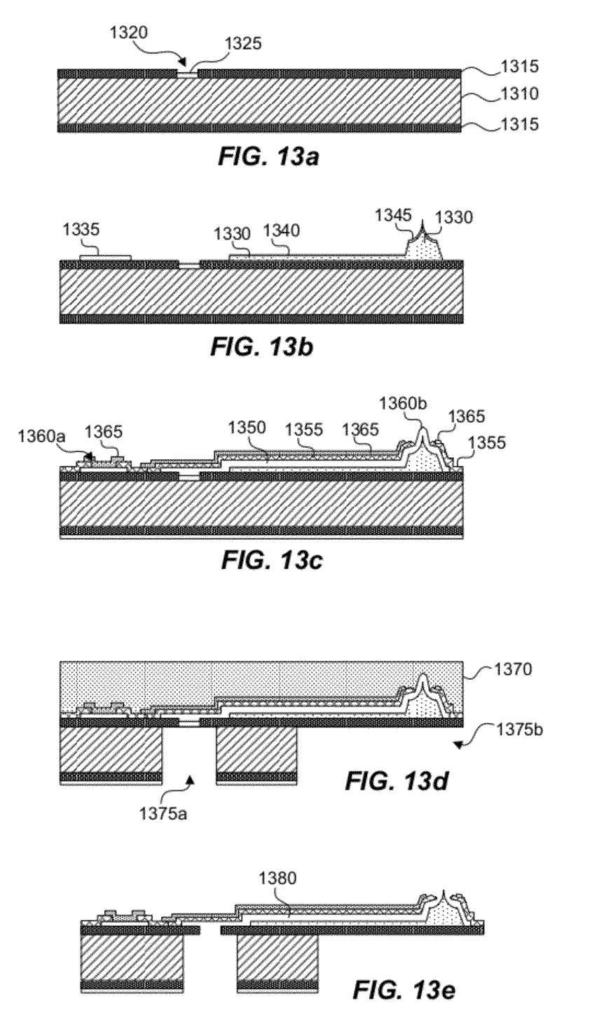

The probes with integrated microfluidic channels are capable of forming extremely localized (˜5-10 nm spot size) plasma-deposition and etching of electronic materials. FIGS. 13a-b show side cross-sectional and top views of a nanotorch probe 1300. The device includes an oxidation sharpened polysilicon tip 1310 coated with a thin layer of refractory metal 1315, SiC or diamond and the tip is protruding out of the interior of a microchannel 1320 through a small (˜3 μm) orifice 1325. A strong refractory metal is desirable to (a) prevent erosion of the tip during etching, and (b) plasma cleaning of any deposited material in a deposition mode. The entire structure can be suspended on a silicon nitride cantilever 1330. The substrate 1335 and cantilever can be mounted on a conventional high-resolution AFM micromanipulator stage with <5 nm positioning resolution. Probes with integrated sense and actuation can be fabricated. The back of the cantilever tip is also coated with a thin reflective metal layer 1340 used to optically determine the vertical tip displacement. To generate nano-plasma, reactive gases (such as SF₆, CHF₃, etc. for etching for example) are introduced into the microchannel inlet 1345. This flow exits the microchannel at the orifice. When a potential difference of a few dozen volts is established between the conductive microchannel walls and the tip, the very high electric field and tunneling electron current (cold cathode emission) present at the sharp tip creates a highly confined plasma region where reactive species responsible for the etching and deposition are generated. These reactive species are transported upwards by the incoming flow toward a sample. In this device, controlled localized etching and deposition is accomplished through: (a) an active gas delivery system that ensures a continuous transfer of new reactive species exiting the tip area and (b) highly localized electric fields near the tip.

A fabrication process can be used in fabricating co-axial tips similar to the tip shown in the SEM image of FIG. 1c. LPCVD (low-pressure chemical vapor deposition) oxide and photoresist can be used as sacrificial layers, oxidation sharpening can be used to form sharp tips, and a thick-photoresist process can be used to pattern co-axial metallic layers above the tip region. The probe shown in FIGS. 13a-b has only one channel. Two or more channel probes along with multiple electrodes connected to apex (highly doped silicon region), tip ring electrode, and top electrodes can also be fabricated.

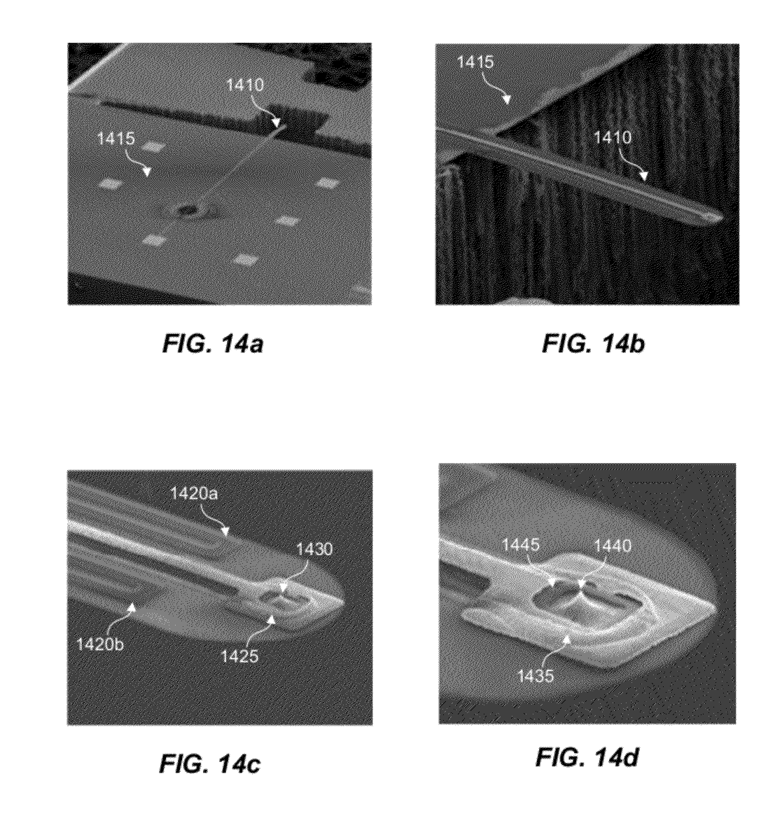

A nanofabrication device can be fabricated as shown in FIGS. 13a-13e. A 2 μm layer of low-stress silicon nitride (Si₃N₄) 1315 is deposited on a silicon (Si) substrate 1310 to provide structural support for the cantilever tip beam. An opening 1320 is etched for a backside access hole. An oxide layer 1325 can form in the access hole and may have a thickness of approximately 0.4 μm. A 6 μm layer of doped LPCVD polysilicon 1330 is deposited over the silicon nitride. The polysilicon can be patterned to form the tip apex and leave a polysilicon layer with a thickness of approximately 1 μm on top of the silicon nitride. Polysilicon piezoresistors 1335 and interconnect lines 1340 to the tip can be defined. The tip can be sharpened by oxidation and a Cr layer 1345 is sputtered and patterned to metalize and harden the tip. A 1 μm of PSG (phosphosilicate glass) sacrificial layer 1350 can be patterned to form the microchannel. A 2 μm wall layer 1355 of low stress Si3N4 is deposited to serve as the wall for the channel and piezoresistor passivation. Contact holes 1360a, 1360b are opened for the piezoresistors and the tip. A lead layer 1365 of Cr/Au is sputtered and patterned to form the electrode leads. Next holes are opened on the Si₃N₄ down to the silicon. A 10 μm layer 1370 of polyimide is spin coated over the structure, which keeps the entire structure frozen while the backside is etched. Backside openings 1375a, 1375b for the gas access hole and beam regions are defined. The wafer backside is etched in a DRIE (deep reactive-ion etch) etchant and half diced. The structure or wafer is exposed to an extended O₂ plasma that releases the entire structure, including from the polyimide spin coat layer. The microchannel is released by sacrificially etching the PSG in HF (hydrofluoric acid). FIGS. 14a-14d show SEM photographs of the device. The cantilever beam 1410 is shown extending from a substrate 1415 in FIGS. 14a-14b. Piezoresistors 1420a, 1420b, a ring electrode 1425 and a tip 1430 are shown in FIG. 14c. The ring electrode 1435, apex 1440, and micro-channel 1445 are visible in FIG. 14d. The device manufactured according to this process was successfully tested in an O₂ environment at atmospheric conditions and with an AC voltage of 1000 V.

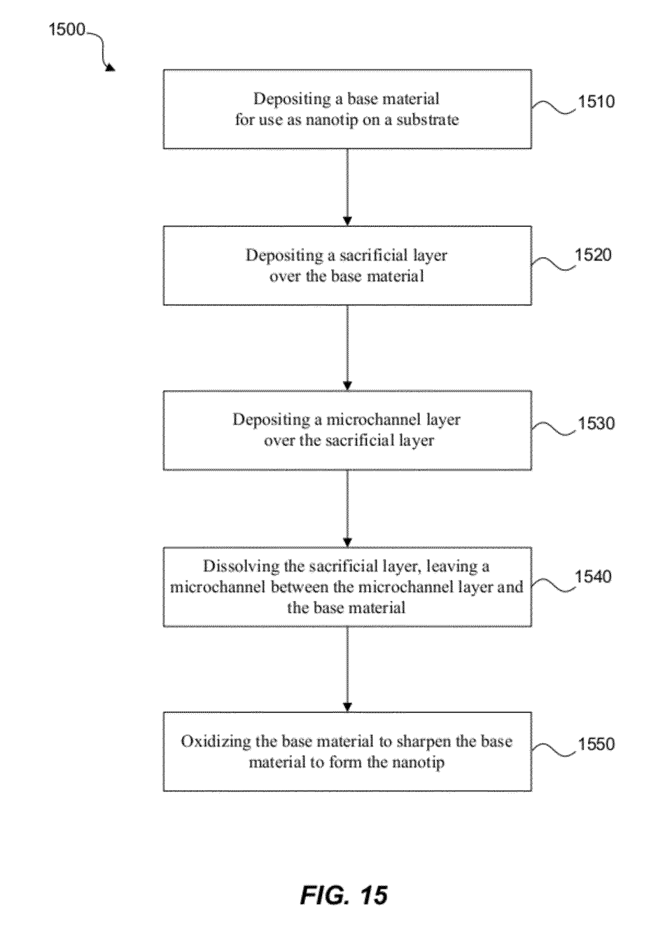

Referring to FIG. 15, a flow diagram of a method 1500 of manufacturing or fabricating a nanofabrication device is shown in accordance with an example of the present technology. The method is similar in many regards to the fabrication process described above, and includes depositing 1510 a base material for use as nanotip on a substrate. A sacrificial layer is deposited 1520 over the base material. A microchannel layer is then deposited 1530 over the sacrificial layer. The sacrificial layer can be dissolved 1540, leaving a microchannel between the microchannel layer and the base material. The base material can be oxidized 1550 to sharpen the base material to form the nanotip. As may be appreciated, the steps of the method are not necessarily in the order presented in the figure, and there may be some degree of interchangeability in the order in which the steps are performed in this method or any other methods or processes described herein.

The method 1500 can further include patterning co-axial metallic layers on the microchannel layer around the nanotip to form a ring electrode around the nanotip.

In one aspect, the nanofabrication device being fabricated can be used to fabricate other nanofabrication devices. Thus, for example, the steps of depositing can be performed using a nanofabrication device comprising a conducting nanotip and a gas microchannel adjacent to the nanotip, the gas microchannel being configured to deliver a gas to the nanotip. In another example, the substrate can be cleaned prior to depositing the base material using the nanofabrication device.

SiC and Diamond-like films can be used to improve the reliability and longevity of the AFM cantilever tips by incorporating these films into the high-wear regions of the structures. Diamond deposition is similar to SiC deposition which will be briefly discussed here. SiC is a desirable choice as a tribological coating, due to chemical inertness, high hardness, and mechanical durability. SiC is also desirable because of an inherent compatibility with Si substrates. One example implementation can utilize single crystal 3C—SiC films applied to Si-based tips while another example implementation can use amorphous hydrogenated SiC films on silicon and silicon nitride based structures. Single crystal 3C—SiC films can be grown directly on Si when using a growth process that involves conversion of the Si surface to 3C—SiC by a process called carbonization. Carbonization is typically performed by exposing a heated Si surface to a gaseous mixture at atmospheric pressure consisting of a hydrocarbon gas that is highly diluted in hydrogen. The substrate temperatures are typically in excess of 1000° C. The carbonization-based 3C—SiC films exhibit the properties required of a high quality tribological coating on Si-based AFM tips. An interface between the 3C—SiC layer and the underlying film will generally be continuous and absent of interfacial voids.

Using conducting substrates, the silicon probe apex can be heated by passing a tunneling current that will carbonize the tip in the presence of methane. Carbonization is temperature and material dependent, so non-Si regions will not be coated as well as Si regions that are below the threshold temperature for carbonization. As a consequence, carbonization, and SiC growth, will occur in the region in which the coating is desired. This process can be repeated to maintain the tip after a few runs. Another method involves the use of amorphous hydrogenated SiC (a-SiC:H) films deposited by PECVD and offers several distinct advantages over carbonization, namely that the substrate temperatures are substantially lower (350° C.) and the coatings can be applied directly to a very wide range of substrate materials, including metals, SiO₂ and Si₃N₄. PECVD processes can be self-applied using these probes. A PECVD process for a-SiC:H can use trimethylsilane as the precursor for use as a solid lubricant in MEMS. Trimethylsilane can be used along with appropriate voltage pulses (polarity and amplitude) to coat the tips with SiC. A molding technique can be used to fabricate SiC and Diamond tips.

Ion-implanted piezoresistive sensors can be integrated on the cantilever beam arm as described to sense the beam deflection caused by the sample pushing back on the tip. Shielding can be used to prevent the actuation voltage applied to the piezoelectric actuators (tens of volts) from coupling to the volt changes detected across the piezoresistors to sense the tip position. Within 0.5-2 nm of the substrate, the vibration amplitude of the probe is modified due to loading effects by the substrate and vibration frequency and damping can be monitored using the piezoresistor or the piezoelectric signal to sense the substrate within 1-2 nm of the apex.

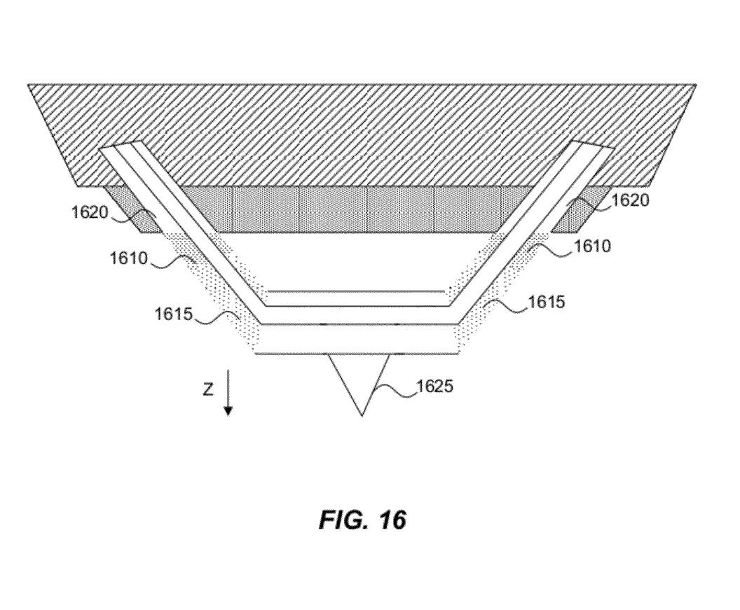

A piezoelectric actuator patch 1610 can be used as schematically shown in FIG. 16 to actuate the probe 1625 in the z-direction. The tip-sample interaction causes the beam to deflect changing the piezoresitors' value. To maintain a constant touching or interaction force, the change in piezoresistors' resistance is monitored and used to provide a feedback to the piezoelectric actuator. A PZT (piezoelectric transducer) ceramic and/or ZnO (zinc oxide) material can be suitable as piezoelectric materials, although other materials can also be used. The actuation of the probe tip parallel to the sample's surface can be achieved using thermal actuators 1615 integrated on a section of the probe arms 1620 as shown in the figure.

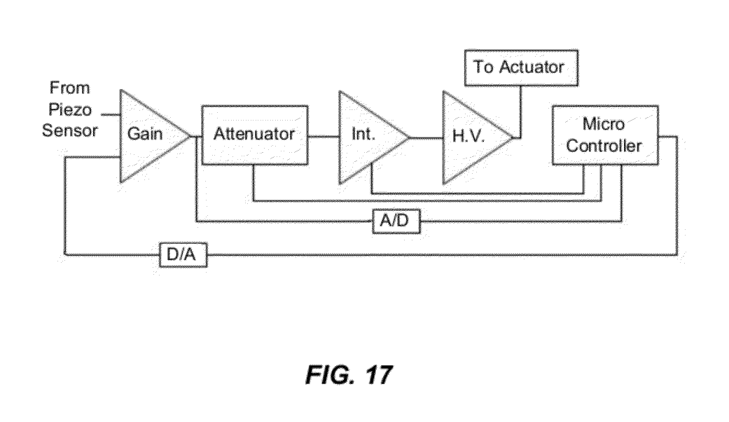

The piezoresistive sensing uses small voltages and currents to measure resistance of a wheatstone bridge. Piezoelectric actuation uses approximately 10-20 volts depending on d₃₁ (piezo strain coefficient) of the material, and a poling state of the material that is used. PZT uses around 10 volts while ZnO uses a few tens of volts. The thermal actuation uses a few mA current at a few volts. Thus, these sense/actuate techniques are relatively low power and can be accomplished using mixed signal IC's. High-gain and up to a few MHz bandwidth amplifiers can be used to amplify micro-volt piezoresistor voltage changes to a few tens of volts necessary to actuate the piezoelectric actuators. The probes and associated sense/actuate/control electronics can be modular to enable large number of probes to operate simultaneously to comply with DARPA GNG metrics of a 30-tip array. Using extensive mixed-signal IC (integrated circuit) designs, a digital controller can be integrated with analog high gain amplifiers and high-voltage (10-20 volts) amplifiers. A block diagram of modular probe sense/control electronics is shown in FIG. 17.

A challenging aspect of this technology is to use the AFM tip to deposit a controlled amount of silicon from silane. The nature of field-ionization in the very narrow inter-electrode gap near the f-AFM tip makes the process somewhat random due to gas density fluctuations. To address this issue, mass spectroscopy, SEM, TEM and finite element modeling can be used to fine tune the deposition and etching parameters to deposit and etch/remove a precise amount of silicon. The arrangement of electrodes, the gap symmetry, the gap distance and the thickness of an insulator layer between the electrodes, the silane to argon and hydrogen ratios, gas pressure and temperature and the excitation method(s) can be adjusted to improve the reproducibility of deposition/etching using the probe.

The functionalized probe tips can be configured to be compatible with existing AFM and can be directly used in the THERMO-MICROSCOPE and NANOSCOPE IV LPM systems. The relationship between the dot size, silane concentration, hydrogen concentration, chamber pressure, temperature, excitation energy and modality (stationary filed, pulsed field, RF, millimeter wave, UV photon energy and intensity, etc.), and the c-AFM tip radius and stand-off distance can be correlated. The electric excitation signal can be applied between the c-AFM tip and the conducting substrate. The UV light can be carried by a UV fiber optic and will illuminate the tip-sample gap. The microwave signal can also be applied externally illuminating the tip-sample region. This arrangement focuses the microwave energy inside the tip-sample gap and is an effective way of bringing in the microwave excitation to affect the gas ionization and does not have to deal with impedance matching in waveguiding the signal to the tip since the technique is a “free-space” technique.

### EXAMPLES

While various examples have been provided above within the description of the technology, two additional examples are also provided below.

In one example, a conducting nanotip, such as an atomic force microscopy (AFM) tip or c-AFM tip, and a metallic substrate (nickel) to demonstrate deposition of silicon quantum dots with the ability to etch and correct their widths and lengths in less than 2 minutes. The two silicon quantum dots can be situated within 50 nm from a reference alignment object on the substrate. A suitable tip material (diamond-like carbon (DLC) and SiC coatings) can be selected to limit the wear in the conducting AFM tip after 100 such operations to less than 10% tip height and less than 20% radius variations. The thermo-microscope's laser probe sensing apparatus can be used to control tip height (from the sample) with better than 20 nm resolution.

In another example, the probes may deposit silicon dots at 1-10 atm Argon pressure with a few percent silane introduced directly nearly the AFM tip using a 100 μm-diameter nozzle appropriately situated to not interfere with the AFM operation. The AFM-sample DC voltages of around 100 Volts with tip-sample stand-off distance of around 5 μm can be used as the starting values. Voltage pulses (ns rise time and durations), as well as AC (6 MHz) signal, millimeter wave signals (100 GHz) externally directed on the AFM apex, and 400 nm UV light guided through UV fiber optic illuminating the AFM apex excitations can all be examined to lower the energy needed for deposition, lower the pressure (to bring it down as close to 1 atmosphere as possible) and reduce the tip-sample distance to around 10-20 nm The probe tip height variation of less than 10% and tip radius variations of less than 20% can be desirable for manufacturing consistency.

While the forgoing examples are illustrative of the principles of the present technology in one or more particular applications, it will be apparent to those of ordinary skill in the art that numerous modifications in form, usage and details of implementation can be made without the exercise of inventive faculty, and without departing from the principles and concepts of the technology. Accordingly, it is not intended that the technology be limited, except as by the claims set forth below.

1. A nanofabrication device, comprising:
a conducting nanotip; and
a gas microchannel adjacent to the nanotip and configured to deliver a gas to the nanotip.

2. A nanofabrication device as in claim 1, further comprising an electrode in electronic communication with a power supply and the nanotip, the electrode being configured to deliver an electric charge from the power supply to the nanotip.

3. A nanofabrication device as in claim 2, further comprising a substrate upon which the conducting nanotip and the gas microchannel are arranged, and wherein the electrode is the substrate.

4. A nanofabrication device as in claim 2, further comprising a non-conducting substrate upon which the conducting nanotip and the gas microchannel are arranged, and wherein the electrode is positioned above the substrate.

5. A nanofabrication device as in claim 1, wherein the nanotip comprises an atomic force microscopy (AFM) tip.

6. A nanofabrication device as in claim 1, further comprising a metallic shield substantially circumscribing the nanotip, the metallic shield comprising a ring electrode.

7. A nanofabrication device as in claim 1, wherein the gas microchannel comprises a plurality of gas microchannels configured to deliver at least two different gases to the nanotip.

8. A nanofabrication device as in claim 1, wherein the nanotip and the gas microchannel comprise an array of nanotips and gas microchannels arranged on a substrate.

9. A nanofabrication device as in claim 1, wherein the conducting nanotip is suspended on an end of a cantilevered arm and further comprising a piezoresistive position sensor and a piezoelectric actuator for sensing and actuating movement of a direction of the nanotip by moving the cantilevered arm.

10. A nanofabrication device as in claim 1, further comprising a silicon carbide film coating on the nanotip.

11. A nanofabrication device as in claim 1, wherein the gas microchannel has an annular outlet which circumscribes the nanotip.

12. A method for nanofabrication, comprising:
positioning a conducting nanotip in a desired location proximal to a substrate;
delivering a precursor gas to the nanotip through a gas microchannel adjacent to the nanotip; and
decomposing the precursor gas to form a solid product by exposing the precursor gas to an electric field using the nanotip such that the solid product deposits on the substrate.

13. A method as in claim 12, wherein the substrate comprises an insulating substrate and positioning the conducting nanotip comprises positioning the conducting nanotip in the desired location proximal to the insulating substrate.

14. A method as in claim 12, further comprising:
positioning the nanotip in a location proximal to the solid product;
delivering a same or different precursor gas to the nanotip through the gas microchannel;
decomposing the same or different precursor gas into argon ions by exposing the same or different precursor gas to an electric field using the nanotip; and
etching the solid product on the insulating substrate using the argon ions.

15. A method as in claim 12, further comprising reversing a polarity of the electric field to switch between causing the solid product to be deposited on the substrate and etching the solid product on the substrate.

16. A method as in claim 12, wherein the nanotip and the gas microchannel respectively comprise an array of nanotips and gas microchannels arranged on a substrate, the method comprising: positioning the array of nanotips, delivering the precursor gas to the array of nanotips through the array of gas microchannels adjacent to the array of nanotips, and decomposing the precursor gas using the array of nanotips.

17. A method as in claim 12, wherein delivering the precursor gas comprises delivering a plurality of different precursor gases substantially simultaneously.

18. A method as in claim 12, further comprising sensing and actuating movement of a direction of the nanotip using a piezoresistive position sensor and a piezoelectric actuator.

19. A method as in claim 12, wherein decomposing comprises transient plasma discharge decomposition.

20. A method as in claim 12, wherein the substrate is a non-conducting substrate.

21. A method of manufacturing a nanofabrication device, comprising:
depositing a base material for use as nanotip on a substrate;
depositing a sacrificial layer over the base material;
depositing a microchannel layer over the sacrificial layer;
dissolving the sacrificial layer, leaving a microchannel between the microchannel layer and the base material; and
oxidizing the base material to sharpen the base material to form the nanotip.

22. A method as in claim 21, further comprising patterning co-axial metallic layers on the microchannel layer around the nanotip to form a ring electrode around the nanotip.

23. A method as in claim 21, wherein the steps of depositing are performed using a nanofabrication device comprising a conducting nanotip and a gas microchannel adjacent to the nanotip, the gas microchannel being configured to deliver a gas to the nanotip.

24. A method as in claim 21, further comprising cleaning the substrate prior to depositing the base material using a nanofabrication device, the nanofabrication device comprising a conducting nanotip and a gas microchannel adjacent to the nanotip, the gas microchannel being configured to deliver a gas to the nanotip.
